(19) United States
(12) Patent Application Publication
(10) Pub. No.: US 2026/0252131 A1
(43) Pub. Date: Aug. 27, 2026

(54) REFERENCE VOLTAGE GENERATOR

(71) Applicant: Samsung Electronics Co., Ltd., Suwon-si (KR)

(72) Inventors: Shubham Raj SINGH, Bengaluru (IN); Nikhil CHOURASIYA, Bengaluru (IN); Subodh Prakash TAIGOR, Bengaluru (IN)

(73) Assignee: Samsung Electronics Co., Ltd., Suwon-si (KR)

(21) Appl. No.: 19/293,805

(22) Filed: Aug. 7, 2025

(30) Foreign Application Priority Data
Feb. 27, 2025 (IN) 202541017405
May 29, 2025 (IN) 202541017405

(51) Int. Cl. G05F 1/46; G05F 1/563; G05F 1/595

(52) U.S. Cl. CPC G05F 1/468; G05F 1/463; G05F 1/563; G05F 1/595

(57) ABSTRACT

A reference voltage generator is disclosed. The reference voltage generator includes a start-up circuit configured to receive an input power supply. The start-up circuit comprises a first set of N-channel Metal-Oxide Semiconductor (NMOS) transistors connected in series. The reference voltage generator further includes a first reference voltage circuit connected to the start-up circuit and configured to generate a Proportional to Absolute Temperature (PTAT) voltage based on the input power supply. The first reference voltage circuit comprises a second set of NMOS transistors coupled with a current mirror circuit. The reference voltage generator also includes a second reference voltage circuit connected to the first reference voltage circuit and configured to generate a Complementary to Absolute Temperature (CTAT) voltage based on the input power supply, the second reference voltage circuit comprises a third set of NMOS transistors. A reference voltage is generated based on the generated PTAT voltage and the CTAT voltage.

### CROSS-REFERENCE TO RELATED APPLICATION(S)

This application claims benefit of priority to Indian Provisional Patent Application No. 202541017405 filed on Feb. 27, 2025 and Indian Non-Provisional Patent Application No. 202541017405 filed on May 29, 2025 the disclosure of which is incorporated herein by reference in its entirety.

### TECHNICAL FIELD

The present disclosure generally relates to reference voltage generators, and more particularly relates to a reference voltage generator for generating a high-speed Process, Voltage, and Temperature (PVT) independent reference voltage for low-voltage applications.

### BACKGROUND

The reliable and efficient generation of reference voltages is advantageous in modern semiconductor devices, for example, in initialization blocks of Not And (NAND) flash systems. The power-up sequence for NAND flash devices may be a complex process, with one of the primary requirements being a fast reference generator. In general, conventional NAND flash systems rely on a Bandgap Reference (BGR) circuit to generate the required reference voltage. However, during initialization or a power-up stage, trim information for the BGR circuit may be unavailable, leading to untrimmed variation in a Band-Gap voltage (VBG) as an output voltage. Moreover, in some applications, a speed of supply ramp-up takes priority over an accuracy of the supply detection.

### SUMMARY

This summary is provided to introduce a selection of example inventive concepts, in a simplified format, that are further described in the detailed description of the present disclosure. This summary is neither intended to identify key or essential inventive concepts of the disclosure nor is it intended to limit the scope of the disclosure.

It will be appreciated that the power budget for the initialization blocks of low power devices is often limited. Various example embodiments of a reference voltage circuit disclosed herein achieves a faster ramp-up time and/or reduces (or minimizes) power consumption.

According to example embodiments of the present disclosure, a reference voltage generator is disclosed. The reference voltage generator includes a start-up circuit configured to receive an input power supply. The start-up circuit includes a first set of N-channel Metal-Oxide Semiconductor (NMOS) transistors connected in series. At least one of the first set of NMOS transistors corresponds to a diode connected NMOS transistor to form a low impendence node. Further, the reference voltage generator includes a first reference voltage circuit connected to the start-up circuit. The first reference voltage circuit is configured to generate a Proportional to Absolute Temperature (PTAT) voltage based on the input power supply. The first reference voltage circuit includes a second set of NMOS transistors coupled with a current mirror circuit. Furthermore, the reference voltage generator includes a second reference voltage circuit connected to the first reference voltage circuit and configured to generate a Complementary to Absolute Temperature (CTAT) voltage based on the input power supply, the second reference voltage circuit includes a third set of NMOS transistors. At least one of the third set of NMOS transistors corresponds to a diode connected NMOS transistor. A reference voltage is generated based on the generated PTAT voltage and the CTAT voltage.

Features and advantages of a reference voltage generator according to various example embodiments disclosed herein may be further understood with reference to the appended drawings. It is appreciated that these drawings do not depict all possible example embodiments of the invention, and are therefore not to be considered as limiting the scope of the appended claims.

Various example embodiments include a reference voltage generator comprising: a start-up circuit configured to receive an input power supply, the start-up circuit comprising a first set of N-channel Metal-Oxide Semiconductor (NMOS) transistors coupled in series, at least one of the first set of NMOS transistors corresponding to a diode connected NMOS transistor configured to form a low impendence node; a first reference voltage circuit coupled to the start-up circuit and configured to generate a Proportional to Absolute Temperature (PTAT) voltage based on the input power supply, the first reference voltage circuit comprising a second set of NMOS transistors coupled to a current mirror circuit; and a second reference voltage circuit coupled to the first reference voltage circuit and configured to generate a Complementary to Absolute Temperature (CTAT) voltage based on the input power supply, the second reference voltage circuit comprising a third set of NMOS transistors, at least one of the third set of NMOS transistors corresponding to a diode connected NMOS transistor, the CTAT voltage configured to be combined with the PTAT voltage to generate a reference voltage.

In some such example embodiments, the reference voltage further comprises a resistive circuit comprising at least one diode-connected MOS resistor, wherein the resistive circuit is configured to generate an independent current output at a common drain-source node of the first reference voltage circuit.

In further example embodiments, the PTAT voltage is generated based on a difference in sizes of NMOS transistors included in the second set of NMOS transistors.

In some example embodiments the reference voltage is generated based on a multiplication of the PTAT voltage and the CTAT voltage.

In further example embodiments, the first reference voltage circuit is further configured to operate a plurality of NMOS transistors in a subthreshold region.

In particular example embodiments, the first reference voltage circuit includes a resistor section and a reference generation branch. The resistor section may a first NMOS transistor configured to operate as a current source, and a plurality of other NMOS transistors configured to operate as resistors.

In other further example embodiments, the PTAT voltage is generated based on a temperature independent bias current.

In yet additional example embodiments, a method includes: receiving an input power supply at a start-up circuit, the start-up circuit including a first set of N-channel Metal-Oxide Semiconductor (NMOS) transistors coupled in series, at least one of the first set of NMOS transistors corresponding to a diode connected NMOS transistor configured to form a low impendence node; providing the input power supply from the start-up circuit to a first reference voltage circuit and a second reference voltage circuit; generating, at the first reference voltage circuit, a Proportional to Absolute Temperature (PTAT) voltage based on the input power supply, the first reference voltage circuit comprising a second set of NMOS transistors coupled to a current mirror circuit; generating, at the second reference voltage circuit, a Complementary to Absolute Temperature (CTAT) voltage based on the input power supply, the second reference voltage circuit comprising a third set of NMOS transistors, at least one of the third set of NMOS transistors corresponding to a diode connected NMOS transistor; and combining the CTAT voltage with the PTAT voltage to generate a reference voltage.

Some such example embodiments further include: generating, at a resistive circuit comprising at least one diode-connected MOS resistor, an independent current output at a common drain-source node of the first reference voltage circuit.

In some example embodiments, generating the PTAT voltage is based on a difference in sizes of NMOS transistors included in the second set of NMOS transistors. Yet other example embodiments include multiplying the PTAT voltage and the CTAT voltage to generate the reference voltage.

Further example embodiments, also include operating a plurality of NMOS transistors included in the first reference voltage circuit in a subthreshold region.

Some example embodiments include: operating a first NMOS transistor included in a resistor section of the first reference voltage circuit as a current source; and operating a plurality of other NMOS transistors included in the resistor section of the first reference voltage circuit as resistors.

In various example embodiments, the PTAT voltage is generated based on a temperature independent bias current.

Some example embodiments of a system include: a voltage divider configured to generate an output including a divided version of a supply voltage;
a reference voltage generator including a startup circuit configured to generate a temperature independent voltage reference (VREF); a comparator configured to process the temperature independent VREF with the output of the voltage divider to generate a comparator output; and a failsafe unit and a hysteresis unit configured to receive the comparator output and generate a power-on Reset signal based on the a comparator output.

In some such example embodiments the reference voltage generator includes: a start-up circuit, the startup circuit being configured to receive an input power supply, the start-up circuit comprising a first set of N-channel Metal-Oxide Semiconductor (NMOS) transistors coupled in series, at least one of the first set of NMOS transistors corresponding to a diode connected NMOS transistor configured to form a low impendence node; a first reference voltage circuit coupled to the start-up circuit and configured to generate a Proportional to Absolute Temperature (PTAT) voltage based on the input power supply, the first reference voltage circuit comprising a second set of NMOS transistors coupled to a current mirror circuit; and a second reference voltage circuit coupled to the first reference voltage circuit and configured to generate a Complementary to Absolute Temperature (CTAT) voltage based on the input power supply, the second reference voltage circuit comprising a third set of NMOS transistors, at least one of the third set of NMOS transistors corresponding to a diode connected NMOS transistor, the CTAT voltage configured to be combined with the PTAT voltage to generate a reference voltage.

In one or more example embodiments, the reference voltage generator further includes: a resistive circuit comprising at least one diode-connected MOS resistor, wherein the resistive circuit is configured to generate an independent current output at a common drain-source node of the first reference voltage circuit.

In further example embodiments, the PTAT voltage is generated based on a difference in sizes of NMOS transistors included in the second set of NMOS transistors. In yet further example embodiments the reference voltage is generated based on a multiplication of the PTAT voltage and the CTAT voltage.

In additional example embodiments, the first reference voltage circuit is further configured to operate a plurality of NMOS transistors in a subthreshold region.

In some example embodiments, the first reference voltage circuit includes a resistor section and a reference generation branch. The resistor section may include a first NMOS transistor configured to operate as a current source, and a plurality of other NMOS transistors configured to operate as resistors.

In yet other example embodiments, the PTAT voltage is generated based on a temperature independent bias current.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 illustrates a Power-on Reset (POR) system;

FIG. 2 illustrates a graphical representation of different voltages of the POR system of FIG. 1;

FIG. 3 illustrates a schematic circuit diagram of a bandgap reference (BGR) device;

FIG. 4 illustrates a block diagram including a charge pump for the BGR device;

FIG. 5 illustrates a schematic circuit diagram of a bandgap reference (BGR) device;

FIG. 6 illustrates a schematic circuit diagram of a bandgap reference (BGR) device;

FIG. 7 illustrates a Power-on Reset (POR) system, according to an example embodiment of the present disclosure; and

FIG. 8 illustrates a schematic circuit diagram of a reference voltage generator, according to the example embodiment of the present disclosure.

Skilled artisans will appreciate that elements in the drawings are illustrated for simplicity and may not have necessarily been drawn to scale. For example, the flow charts illustrate the method in terms of the most prominent steps involved to help improve understanding of aspects of the present disclosure. Furthermore, in terms of the construction of the device, one or more components of the device may have been represented in the drawings by conventional symbols, and the drawings may show only those specific details that are pertinent to understanding the example embodiments of the present disclosure so as not to obscure the drawings with details that will be readily apparent to those of ordinary skill in the art having the benefit of the description herein.

### DETAILED DESCRIPTION

For the purpose of promoting an understanding of the principles of the disclosure, reference will now be made to the various example embodiments, and specific language will be used to describe the same. It will nevertheless be understood that no limitation of the scope of the disclosure is thereby intended. Alterations and further modifications to various illustrated example embodiments, and such further applications of the principles of the disclosure as illustrated therein, may be made by one skilled in the art.

It will be understood by those skilled in the art that the foregoing general description and the following detailed description are explanatory of the invention and are not intended to be restrictive thereof.

Reference throughout this specification to “an aspect”, “another aspect” or similar language means that a particular feature, structure, or characteristic described in connection with an example embodiment may be included in at least one example embodiment of the present invention. Thus, appearances of the phrase “in an example embodiment”, “in another example embodiment” and similar language throughout this specification may, but do not necessarily, all refer to the same example embodiment.

The terms “comprises”, “comprising”, or any other variations thereof, are intended to cover non-exclusive elements, such that a process or method that comprises a list of steps may include other steps not expressly listed in such a process or method. Similarly, one or more devices or sub-systems or elements or structures or components proceeded by “comprises . . . a” does not, without more constraints, preclude the existence of other devices, other sub-systems, other elements, other structures, other components, additional devices, additional sub-systems, additional elements, additional structures, or additional components.

As is traditional in the field, example embodiments may be described and illustrated in terms of blocks that carry out a described function or functions. These blocks, which may be referred to herein as units, modules, the like, may be physically implemented by analog or digital circuits such as logic gates, integrated circuits, microprocessors, microcontrollers, memory circuits, passive electronic components, active electronic components, optical components, hardwired circuits, or the like, and may optionally be driven by firmware and/or software. The circuits may, for example, be embodied in one or more semiconductor chips, or on substrate supports such as printed circuit boards or the like. The circuits constituting a block may be implemented by dedicated hardware, or by a processor (e.g., one or more programmed microprocessors and associated circuitry), or by a combination of dedicated hardware to perform some functions of the block, and a processor to perform other functions of the block. Each block may be physically separated into two or more interacting and discrete blocks without departing from the scope of the invention. Likewise, the blocks may be physically combined into more complex blocks without departing from the scope of the disclosure.

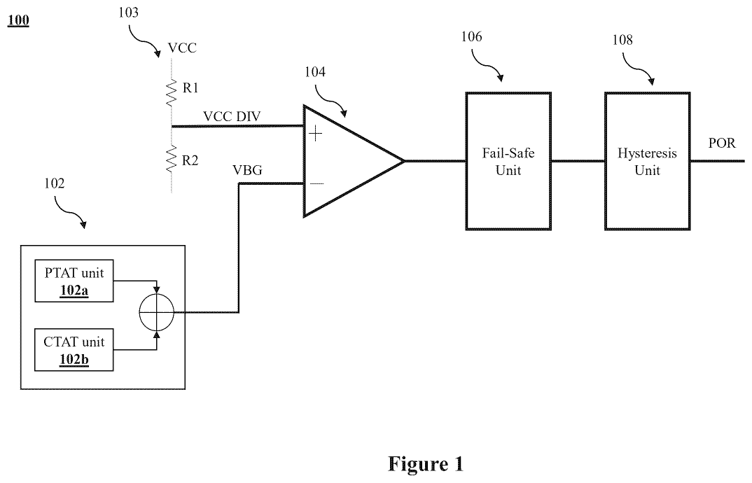

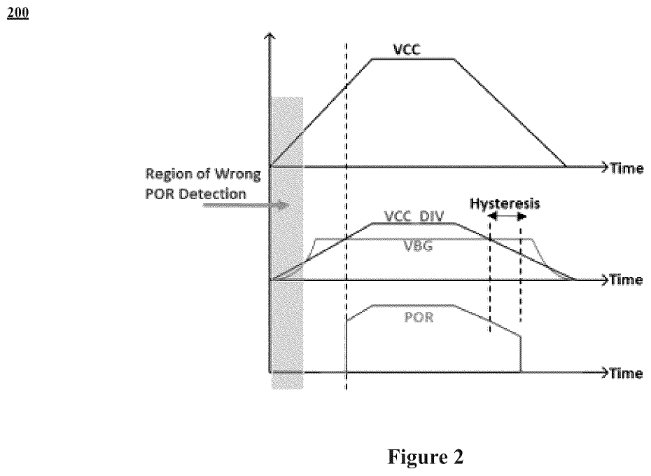

FIG. 1 illustrates a Power-on Reset (POR) system 100. FIG. 2 illustrates a graphical representation 200 of different voltages of the POR system 100. The POR system 100 ensures that a device (for example, a Not And (NAND) flash device) initializes correctly at startup. The POR system 100 generates a brief reset signal that holds the device in a reset state until a power supply stabilizes. The POR system 100 includes a bandgap circuit 102, a voltage divider 103, a comparator 104, a fail-safe unit 106, and a hysteresis unit 108. The bandgap circuit 102 is configured to generate a stable reference voltage (VBG) that is not affected by a supply voltage (VCC) variations or temperature changes. In some examples, this stable voltage can be around 1.2V, which is the typical bandgap voltage for silicon. The bandgap circuit 102 may include a Proportional to Absolute Temperature (PTAT) unit 102a and a Complementary to Absolute Temperature (CTAT) unit 102b. The PTAT unit 102a generates a voltage that increases with temperature, while the CTAT unit 102b produces a voltage that decreases with temperature. The combination of the PTAT unit 102a and the CTAT unit 102b helps to create a stable output voltage that is largely independent of temperature variations.

The voltage divider 103 is configured to set appropriate threshold levels. An output of the voltage divider 103 sets a voltage level (for example, the VCC DIV) that will determine when the reset signal is asserted (active low or high). The comparator 104 is configured to compare the two voltages (i.e., the VCC DIV and the VBG) to generate the reset signal.

The fail-safe unit 106 ensures that if the device enters a fault condition (e.g., if the supply voltage drops unexpectedly), the reset signal will be asserted. In some cases, the fail-safe unit 106 asserts the reset signal if the voltage falls below a critical threshold value.

The hysteresis unit 108 is configured to remove noise and/or chatter from the reset signal. Specifically, the hysteresis unit 108 is configured to maintain reset condition even if the VCC experiences minor fluctuations.

In general, the PTAT unit 102a generates a PTAT voltage (VPTAT) using the following equation (1):

$$VPTAT = {A}_{1} + {B}_{1} T \qquad ( 1 )$$

In the equation (1), A₁ represents a constant that represents a voltage offset at 0 Kelvin (absolute zero), B₁ represents a PTAT coefficient corresponding to a rate of change of voltage with respect to temperature, and T is the absolute temperature in Kelvin.

The CTAT unit 102b generates a CTAT voltage (VCTAT) using the following equation (2):

$$VCTAT = {A}_{2} - {B}_{2} T \qquad ( 2 )$$

In the equation (2), A₂ represents a constant that represents a voltage offset at 0 Kelvin (absolute zero), B₂ represents a CTAT coefficient corresponding to a rate of change of voltage with respect to temperature, and T is the absolute temperature in Kelvin.

Further, the bandgap reference voltage (VBG) is given by the following equation (3):

$$VBG = VPTAT + VCTAT \qquad ( 3 )$$

The bandgap circuit 102 adjusts the coefficients B₁ and B₂ to cancel the first order temperature dependence and generate the VBG.

The POR system 100 is generally implemented at the NAND flash devices. However, a power-up scheme of such NAND flash devices is complex with one of most essential requirement of fast reference voltage generation. Conventional POR systems (for example, the POR system 100) rely on the bandgap circuit 102 for said reference voltage.

During initialization (i.e., power-up), trim information of the bandgap reference is not available, leading to untrimmed variation in the VBG. In applications, where a speed of supply ramp-up is preferred over accuracy of supply detection such variation is not a concern.

However, the challenges with such POR systems or bandgap reference circuits are fast ramp-up time, combined with a low power consumption, as power budget is generally low for such initialization blocks.

As shown in FIG. 2, a maximum possible supply ramp rate is limited by the ramp-up time of the bandgap reference voltage (VBG).

Specifically, a slow bandgap reference leads to a slower supply ramp. Further, the slow bandgap reference requires a complex fail safe unit to avoid region of wrong POR detection, as shown in FIG. 2. Moreover, additional components slow down an overall signal flow within the device.

A slow BGR during an initialization sequence can result in several issues, including a slower supply ramp, a more complex fail-safe design to prevent incorrect POR detection, and the addition of extra digital circuitry to deliberately slow down signal flow.

In an example, a fast ramp-up rate of supply of the order of 1V/4 μs with a ramping up of the VBG at 1.8V, an available time (tᵣₐₘₚ) for the VBG to ramp-up and detect the VCC of 2.2V will be defined by the following equation (4):

$${t}_{ramp} = 4 μ s * ( 2.2 - 1.8 ) = 1.6 μ s \qquad ( 4 )$$

Thus, for a budget of order of 10 μA, the design of the bandgap reference (BGR) circuit becomes challenging.

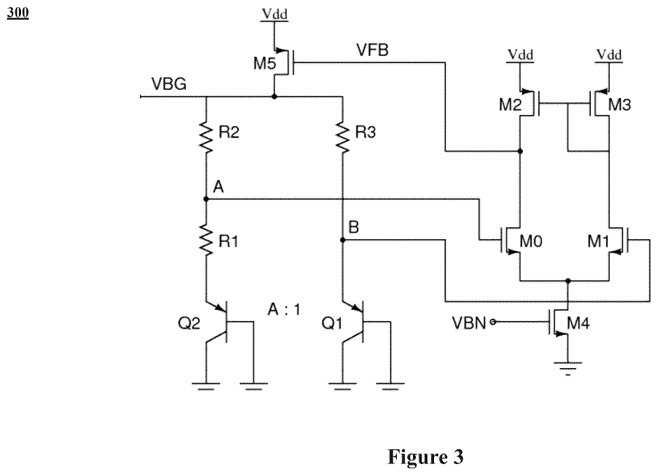

FIG. 3 illustrates a schematic circuit diagram of a bandgap reference device 300 (hereinafter interchangeably referred to as BGR 300). The BGR 300 is a type of reference voltage generator commonly used in integrated circuits. The BGR 300 includes two bipolar junction transistors (BJTs) (i.e., Q1 and Q2) to generate the VBG, which is largely independent of temperature variations. The BGR 300 may correspond to Modified Kujiks Bandgap Reference circuit. In FIG. 3, transistors M0, M1, M2, M3, M4 form a single stage amplifier. Furthermore, resistors R1, R2, R3, transistor M5, and the transistors Q1 and Q2 form a core of the BGR 300. The single stage amplifier makes Node A equal to Node B, due to negative feedback. So, a ΔVBE is created across the resistor R1, thus a PTAT current I_{PTAT}=ΔVBE/R1 flows through both Q1 and Q2 branches of the BGR core. Therefore, the VBG may be given by following equation:

$$VBG = VBE + {I}_{PTAT} * R 2.$$

$$keep R 2 = R 3.$$

To improve the performance, the BGR 300 is dedicated to an initialization sequence block, and has no enable signal. In addition, low threshold voltage (V_{TH}) transistors are used so as to make the BGR 300 faster. Moreover, the transistors M0 and M1 may be kept as depletion transistors to support Internal Current Mirror Reference (ICMR), and exploit high mobility of the transistors M0 and M1. The transistors M0 and M1 are implemented as N-Channel Metal-Oxide Semiconductor (NMOS) transistors.

In an example, for a fast start-up circuit, the settling time provided by the BGR 300 is given by the following equation (5):

$${T}_{s} ∝ \frac{1}{UGB} , where UGB is unity gain frequency \qquad ( 5 )$$

Therefore, for a faster response, such BGR circuits require higher UGB which is in contradiction to low power operations. Moreover, such BGR circuits limit the supply ramp rate in devices (for example, the NAND flash devices).

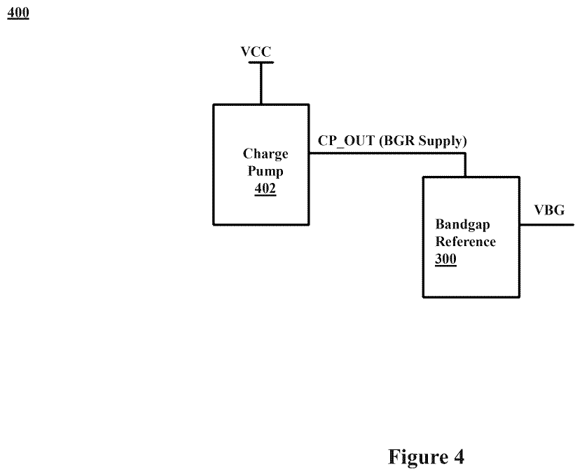

FIG. 4 illustrates a block diagram 400 including a charge pump 402 for the BGR device 300. To improve the supply ramp rate, the charge pump 402 is implemented. The charge pump 402 amplifies an effective supply voltage supplied to the BGR 300. When the input voltage supply (VCC) is at a lower level, the charge pump 402 amplifies the input voltage supply (VCC) to generate an output voltage (CP_OUT) which is fed to the BGR 300. Thereafter, the BGR 300 generates the bandgap reference voltage (VBG) based on the CP_OUT. In some examples, with the illustrated architecture of FIG. 4, the BGR 300 starts working at a supply of 1.25*VTH_{NMOS} and supports a ramp speed of 1V/4 μs. Moreover, the charge pump 402 includes lower value capacitors for fast operation. However, the BGR 300 with such configuration (including the charge pump 402) increases area consumption, and high transient power consumption during device initialization, which is not desirable.

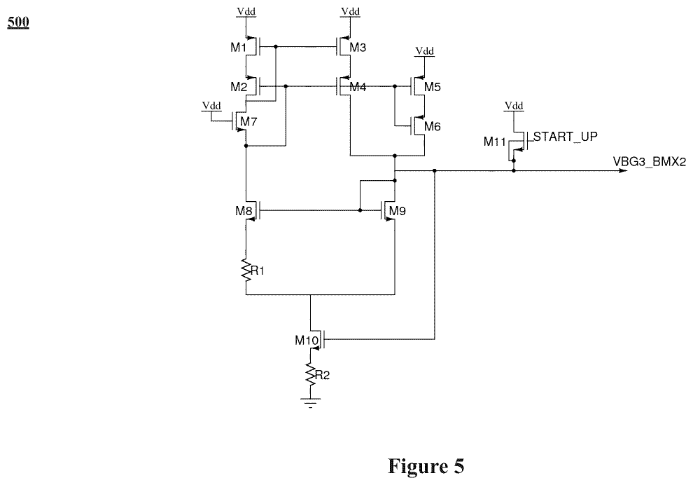

FIG. 5 illustrates a schematic circuit diagram of a bandgap reference (BGR) device 500. The BGR device 500 may include transistors M1, M2, M3, M4, and M7. The transistors M1, M2, M3, M4, and M7 may form a cascade current mirror. Further, transistors M9 and M8 operate in subthreshold region, thus a gate voltage of transistor M9 (VG_{M9}) is CTAT in nature. A PTAT current (I_{PTAT}) is generated by the transistors M9, M8, and resistor R1, which is equal to (V_{GSM9}−VGS_{M8})/R1. Thus VBG3_BMX2=VGS_{M9}+I_{PTAT}*(R2+r_{M10}), where transistor M10 is acting as a linear resistor and is in linear region. Further, r_{M10} may correspond to a resistor of the transistor M10.

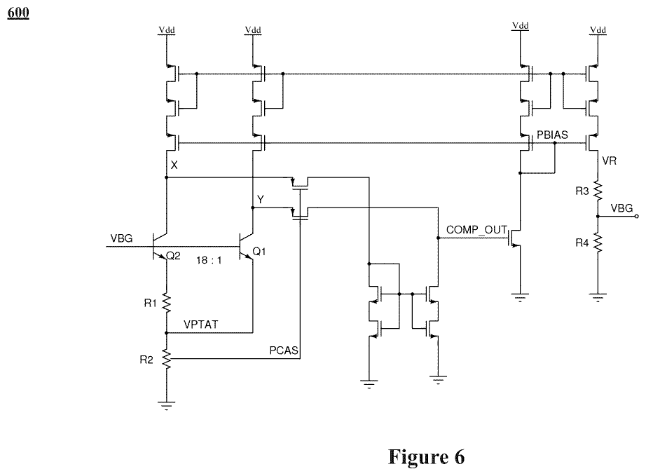

FIG. 6 illustrates a schematic circuit diagram of a bandgap reference (BGR) device 600. The BGR device 600 may include a current comparator-based Brokaw's BGR. Unlike other traditional BGR devices (such as the one in FIG. 3), where amplifiers are used to make two voltages equal, the BGR 600 compares currents using current comparators and feeds the result back into the core of the BGR circuit. The BGR device 600 tends to be very slow, but very accurate. The requirement chooses speed over accuracy, hence the BGR device 600 is not suitable.

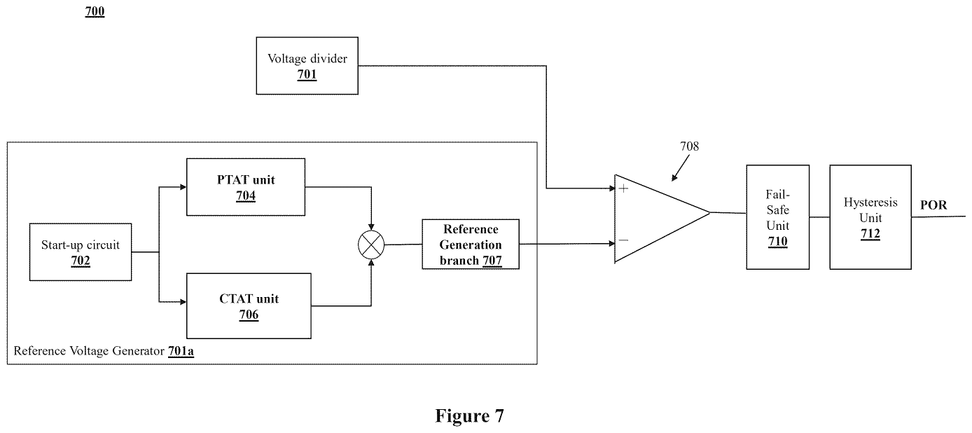

FIG. 7 illustrates a Power-on Reset (POR) system 700, according to an example embodiment of the present disclosure. The POR system 700 may include a voltage divider 701, a reference voltage generator 701a comprising a startup circuit 702, a PTAT unit 704, and a CTAT unit 706, a comparator 708, a fail-safe unit 710, and a hysteresis unit 712. The POR system 700 may be used to perform temperature compensation on a reference signal and/or the reset signal. For example, the POR system 700 may generate a reference voltage, that remains stable across temperature variations by combining a PTAT component and a CTAT component of the input voltage. The PTAT component may be generated by the PTAT unit 704 and the CTAT component may be generated by the CTAT unit 706. For example, the PTAT 704 may be referred to as a first reference voltage circuit, and the CTAT 706 may be referred to as a second reference voltage circuit.

In an example embodiment, the startup circuit 702 may be configured to initialize the POR system 700 by feeding the input supply voltage (VCC) to the core of the reference voltage generator 701a including the PTAT unit 704 and the CTAT unit 706. In one or more example embodiment, the start-up circuit 702 comprises a first set of NMOS transistors connected in series. In one or more example embodiment, one or more NMOS transistors from the first set of NMOS transistors may correspond to a diode connected NMOS transistor to form a low impendence node.

In an example embodiment, the PTAT unit 704 may be connected to the startup circuit 702. The PTAT unit 704 may generate the PTAT component i.e., a voltage proportional to temperature. The PTAT unit 704 may also employ one or more diode-connected NMOS transistors to ensure reliable startup under varying temperature conditions. In an example embodiment, the PTAT unit 704 may be configured to generate the PTAT component (interchangeably referred to as the PTAT voltage) by exploiting difference in sizes of the one or more NMOS transistors configured in a current mirror circuit. Such a design of the PTAT unit 704 may ensure an operation in a subthreshold region, which minimizes power consumption and enhances temperature compensation. The PTAT voltage may be determined by the PTAT unit 704 using the following equation (6).

$$VPTAT = {A}_{3} * {T}^{p + 1} \qquad ( 6 )$$

In the equation (6), A₃ represents an empirical constant which can be derived from experimentation. Further, the variable “p” may be adjusted by changing width-to-length (W/L) ratios of the one or more transistors from among the first set of NMOS transistors.

The CTAT unit 706 may be configured to generate the CTAT component (interchangeably referred to as the CTAT voltage) using one or more diode-connected NMOS transistors and a MOS resistor. The CTAT voltage is critical for balancing the temperature dependence of the PTAT voltage. The CTAT unit 706 may be connected to the PTAT unit 704 and may provide a voltage inversely proportional to temperature. The CTAT voltage may be determined by the CTAT unit 706 using the following equation (7).

$$VCTAT = {A}_{4} / {T}^{m} \qquad ( 7 )$$

In the equation (7), A₄ represents a constant that represents a voltage offset at 0 Kelvin (absolute zero). Further, the variable “m” may represent temperature dependence of mobility of a Complementary Metal-Oxide Semiconductor (CMOS) transistor implemented at the CTAT unit 706, which ranges from 1.5V-2V.

The PTAT voltage and the CTAT voltage may be combined to generate a Process, Voltage, and Temperature (PVT) independent reference voltage (VREF). The combined voltage reference output (i.e., the VREF) may be determined using the following equation (8):

$$VREF = {A}_{3} * {A}_{4} * {T}^{( p + 1 - m )} \qquad ( 8 )$$

In one embodiment, the reference voltage generator 701a may include a reference generation branch 707. Further, a multiplication of the PTAT voltage and the CTAT voltage may generate a ZTAT current. The generated ZTAT current may be used by the reference generation branch 707 to generate the reference voltage VREF.

Hence, the system 700 achieves precise compensation by adjusting the coefficients of the PTAT and CTAT voltages.

The comparator 708 may be configured to process the generated reference voltage (VREF) with a divided version of a supply voltage from the voltage divider 701 to the generate the reset signal. An output of the comparator 708 may be further processed by the fail-safe unit 710 and the hysteresis unit 712 to ensure stability and noise immunity before generating a final POR signal. The POR signal ensures reliable initialization of electronic systems during power-up or under varying temperature conditions. In one example embodiment, the fail-safe unit 710 and the hysteresis unit 712 may be similar to the fail-safe unit 106 and the hysteresis unit 108 (as shown in FIG. 1), respectively.

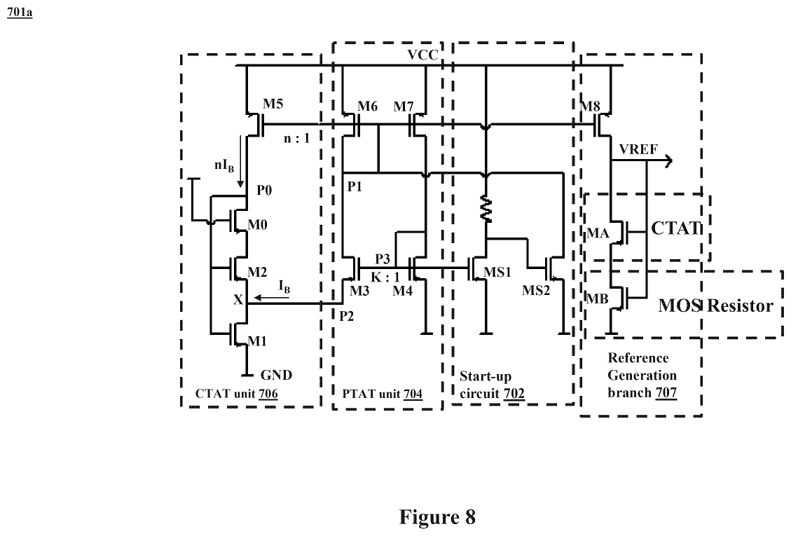

FIG. 8 illustrates a schematic circuit diagram of the reference voltage generator 701a, according to the example embodiment of the present disclosure. FIG. 8 illustrates a configuration of a plurality of NMOS transistors in subthreshold operation and coupling of the plurality of NMOS transistors with a current mirror circuit. The reference voltage generator 701a may include a CTAT unit 706 configured to generate the CTAT voltage. The CTAT unit 706 may include Metal-Oxide Semiconductor (MOS) resistors i.e., M0, M1, and M2. In one example embodiment, the MOS resistors M0, M1, and M2 form a PTAT MOS resistor, where a node “X-to-Ground (GND)” acts as a resistor. In the illustrated example embodiment, the M1 and M0 may be in deep triode region and the M2 is in saturation region. In one example embodiment, the node X may have a voltage of about 100-150 mV. Moreover, a size of the M1 may be selected such that the M1 stays in the triode region across a corner. Moreover, MOS transistors M3 and M4 may be in sub-threshold regions.

In the example embodiment, a bias current (I_{B}) that is temperature-independent is achieved by adjusting sizes of the MOS transistors M1, M2 and a scaling factor ‘k’ to cancel out the temperature dependence of the generated bias current (I_{B}). The node X may be crucial for generating the PTAT voltage. In one embodiment, MOS transistors M6, M7, M3, and M4 may form the PTAT unit 704. In the circuit, transistors M6 and M7 are biased in the saturation region, where they function as a current mirror, ensuring that the currents in both branches are matched. In contrast, transistors M3 and M4 operate in the subthreshold region, producing a voltage at node X that corresponds to the difference in their gate-source voltages (VGS). Specifically, this voltage is given by VT*ln(k), where VT denotes the thermal voltage and k is a constant. The resulting voltage at node X exhibits a PTAT characteristic. Since the M1 and M0 are in the deep triode region, the M1 and M0 may behave like resistors, while the M2 is in the saturation region, and therefore the M2 may act as a current source. This voltage difference at the node X results from the PTAT voltage, which is dependent on temperature.

In one or more example embodiments, the bias current (I_{B}) may be generated using the following equation (9),

$${I}_{B} = k ( {VGS}_{1} - Vth ) * {V}_{T} ln K \qquad ( 9 )$$

The above equation (9) may be derived using the following equations (9a)-(9c):

$$( n + 1 ) {I}_{B} = k ( {V}_{GSM 1} - {V}_{th} ) {V}_{X} \qquad ( 9 a )$$

$${I}_{B} = {V}_{T} ( ln K ) \frac{1}{{R}_{INX}} \qquad ( 9 b )$$

$${R}_{INX} = \frac{{V}_{X}}{( n + 1 ) {I}_{B}} \qquad ( 9 c )$$

In the equations (9) and (9a)-(9c), I_{B} represents the bias current, which is the current being generated by the PTAT unit 704, ‘k’ is the scaling factor, V_{GSM1} is the gate-to-source voltage of the M1, and Vₜₕ is a threshold voltage of the transistor M1, V_{X} is voltage at the node X, which is temperature-dependent, contributing to the generation of the PTAT voltage. The equation indicates that the bias current I_{B} depends on the temperature through the voltage V_{X} and the term V_{GSM1}−Vₜₕ. The temperature dependence of these quantities results in the bias current I_{B} that is also dependent on temperature. Further, V_{T} is thermal voltage (which depends on temperature); ln(K) is logarithmic dependence of the current on the factor k. R_{INX} represents resistance at the node X, and the R_{INX} is related to the voltage at the node X and the bias current I_{B}. The resistance R_{INX} is temperature-dependent, meaning it affects how the bias current is generated.

Thus, the equation (9) shows that the bias current I_{B} depends on V_{GSM1}−Vₜₕ (which has a temperature dependence), V_{T} (the thermal voltage, which increases with temperature), and the factor k. The factor k is defined as k∝T^{-m}, where T is the temperature (in Kelvin) and m is a constant that ranges between 1.5 and 2, depending on the specific design and process. By carefully adjusting the sizes of the M1 and M2 (which affect V_{GSM1}−Vₜₕ) and the scaling factor k, the design aims to cancel the temperature dependence of the bias current I_{B}. Adjusting the sizes of the M1 and M2, the gate-to-source voltage of the M1 and the threshold voltage Vₜₕ are made temperature-independent. By sizing the M1 appropriately, an amount of temperature-induced variation in V_{GSM1}−Vₜₕ may be controlled. Further, as the scaling factor k has an inverse temperature dependence (as k∝T^{-m}), thus selecting a right value for k can cancel curvature of the bias current I_{B}.

For the M1, an exemplary equation for the bias current I_{B} may be defined as the following equation (10),

$${I}_{B} = {k}_{1} ( {V}_{G 1} - {V}_{TH} ) {V}_{D S 1} \qquad ( 10 )$$

Further, the V_{G1} and the VGS_{M1} may be essentially same given a source of the M1 is at ground.

For the M2, an example equation for the bias current I_{B} may be defined as the following equation (11):

$${mI}_{B} = {{k}_{2} ( {V}_{G s 2} - {V}_{TH} )}^{2} \qquad ( 11 )$$

To simplify, VGS₂ may be equated to V_{G1} assuming the M1 in deep triode region. Thereafter, equating the above equations (10) and (11), the following equation (12) may be obtained as:

$${V}_{G 1} = {V}_{TH} + k 1 / k 2 \qquad ( 12 )$$

Substituting value of V_{G1} in the equation (9), the following equation (13) for determining the bias current I_{B} may be obtained:

$${I}_{B} = {k}_{1} ( \frac{{k}_{1}}{{k}_{2}} {V}_{D S 1} ) * {V}_{T} * ln ( K ) \qquad ( 13 )$$

Therefore, by adjusting the k1/k2 ratio, the I_{B} may be adjusted.

In one or more example embodiment, the reference voltage may be expressed by the following equation (14):

$$VREF = {VDS}_{MA} + {VGS}_{MB} \qquad ( 14 )$$

In the equation (14), the VGS_{MB} is the CTAT voltage as a transistor MB is operating in subthreshold.

Further,

$${VDS}_{MA} \approx \frac{{mI}_{B}}{k ( {VGS}_{MB} - Vth )} ; Also , {VGS}_{MB} - Vth = η {V}_{T} ln ( \frac{{mI}_{B}}{{I}_{S}} ) ,$$

where symbols have generic meaning, and a transistor MA is in deep triode region.

Based on the above, the, VDS_{MA} may be obtained using the following equation (15):

$${VDS}_{MA} = \frac{{mI}_{B}}{k ( η {V}_{T} ln ( \frac{{mI}_{B}}{{I}_{S}} ) )} ; where k ∝ \frac{1}{{T}^{- 2}} , and {V}_{T} ∝ T \qquad ( 15 )$$

Further, the VDS_{MA} may act as the PTAT voltage.

Furthermore, as

$${VGS}_{MB} = Vth + η {V}_{T} ln ( \frac{{mI}_{B}}{{I}_{S}} ) ,$$

and Vₜₕ may be expressed as A−BT, where A and B are the relevant coefficients.

So,

$$VREF = [ Vth + η {V}_{T} ln ( \frac{{mI}_{B}}{{I}_{S}} ) ] + {VDS}_{MA} ;$$

As expressed already,

$${VDS}_{MA} = \frac{{mI}_{B}}{k ( η {V}_{T} ln ( \frac{{mI}_{B}}{{I}_{S}} ) )}$$

Therefore, the VREF may be expressed by the following equation (15):

$$VREF = [ Vth + η {V}_{T} ln ( \frac{{mI}_{B}}{{I}_{S}} ) ] + \frac{{mI}_{B}}{k ( η {V}_{T} ln ( \frac{{mI}_{B}}{{I}_{S}} ) )} \qquad ( 15 )$$

$$Also ,$$

$$η {V}_{T} ln ( \frac{{mI}_{B}}{{I}_{S}} ) = C T \qquad ( 16 )$$

So,

$$VREF = [ Vth + CT ] + \frac{{mI}_{B}}{kCT} ;$$

where k=μₙ Cₒₓ W/L, and k=DT⁻², or

$$VREF = [ Vth + CT ] + \frac{{mI}_{B}}{CT * {DT}^{- 2}} , or VREF = [ A - BT + CT ] + \frac{{mI}_{B}}{CD} T$$

Upon differentiating both sides w.r.t T,

$$\frac{\partial VREF}{\partial T} = - B + C + \frac{{mI}_{B}}{CD} = 0 \qquad ( 17 )$$

$$Furthermore ,$$

$$C + \frac{{mI}_{B}}{CD} = B \qquad ( 18 )$$

In the equation (18), B is slope of the CTAT and (C+mI_{B}/CD) is the slope of the PTAT, which can be altered using W/L of the transistor MB and m to attain first order curvature cancellation. It must be noted that multiple simplifications have been assumed to demonstrate the validity of the above equations. FIG. 8 further illustrate the start-up circuit 702. The start-up circuit 702 may include a pair of MOS transistors i.e., MS1 and MS2. When the bandgap reference circuit is in an undesired state, characterized by a zero output voltage, a startup mechanism is triggered to ensure proper circuit operation. Specifically, when the current through the circuit is zero, the drain voltage of transistor MS1 (VD(MS1)) equals the supply voltage VDD. This condition also sets the gate voltage of transistor MS2 (VG(MS2)) to VDD, thereby turning MS2 on. As a result, the P1 node is pulled down, allowing an inrush current to flow through transistors M6 and M7. The finite current through M4 is mirrored to MS1, decreasing VD(MS1)=VG(M2) and disconnecting the startup circuit, thereby enabling stable operation of the bandgap reference. The reference voltage generator 701a may further include the reference generation branch 707. The reference generation branch 707 may include the MOS transistor M8, and a pair of MOS resistors MB and MA. The gate voltage of transistor MB is higher than its drain voltage, causing it to operate in the deep triode region. As a result, the resistance provided by MB can be expressed as

$$R = \frac{1}{{μ}_{n} Cox \frac{W}{L} ( {V}_{ref} - {V}_{th} )} .$$

As the temperature increases, the mobility effect dominates, and since μ_n∝T−2, the resistance R increases with temperature, exhibiting a PTAT (proportional to absolute temperature) characteristic. The current through transistor MB is given by m*I_{B}, which is ZTAT (zero temperature coefficient) in nature.

The voltage across MB, VDS(MB), is the product of the current and resistance, and therefore exhibits a PTAT characteristic. Transistor MA is diode-connected, and the voltage across it is CTAT (complementary to absolute temperature) in nature. The reference voltage, VREF, is the sum of the voltages across MA and MB, which can be expressed as VREF=VCTAT+VPTAT, where VCTAT is the CTAT voltage across MA and VPTAT is the PTAT voltage across MB. This combination of CTAT and PTAT voltages results in a reference voltage that is relatively insensitive to temperature variations.

Further, FIG. 8 illustrates different poles P0-P3 that provide low impedance and high speed operation. The low impedance may be provided by the diode-connected MOS transistors M0, M6 and M4.

Further, in case a capacitor is connected to each of the poles (for example, a capacitor C0 is connected at Pole P0, C1 is connected at P1, C2 is connected P2, and C3 is connected at P3), the speed at each pole may be defined by the following Table 1:

TABLE 1

| | |
|---|---|
| P0 | $\approx \frac{g m 2}{C 0}$ |
| P1 | $\approx \frac{g m 6}{C 1}$ |
| P2 | $\approx \frac{gds 1 \vert \vert gm 3}{C 2}$ |
| P3 | $\approx \frac{g m 4}{C 3}$ |

Since gm6 comes from the current mirror, and it is supposed to have lowest GM by design (for low mirror mismatch), Therefore, dominant pole will be formed by the P1. In case, the C1 is of the order of 50-100 pF, and gm6 of the order of 60 S, dominant pole is expected at a frequency of 50-100 MHz, thus ensuring a high speed for the circuit.

In some example embodiments, the POR system 700 may be implemented with a plurality of voltage dividers 701, the reference voltage generators, and a plurality of gate drivers and latch circuit to ramp up supply voltage.

At least some example embodiments disclosed herein may avoid use of a dedicated fast BGR for the initialization block, offering multiple BGR options as backups, or using a backup POR generator to ensure timely power-up within a ±15-18% accuracy range. Other example embodiments may further avoid using a charge pump doubler to boost the effective supply voltage of the BGR during low VCC condition.

The units and/or modules described herein may be implemented using hardware components or a combination of software components and hardware component. For example, the hardware components may include microcontrollers, memory modules, sensors, amplifiers, band-pass filters, analog to digital converters, and processing devices, or the like. A processing device may be implemented using one or more hardware device(s) configured to carry out and/or execute program code by performing arithmetical, logical, and input/output operations. The processing device(s) may include a processor, a controller and an arithmetic logic unit, a digital signal processor, a microcomputer, a field programmable array, a programmable logic unit, a microprocessor or any other device capable of responding to and executing instructions in a defined manner. the processor may be a hardware processor such as central processing unit (CPU), a multi-processor, a distributed processing system, an application specific integrated circuit (ASIC), and/or a suitable hardware processing unit. The processing device(s) may run an operating system (OS) and one or more software applications that run on the OS. The processing device also may access, store, manipulate, process, and create data in response to execution of the software. For purpose of simplicity, the description of a processing device is used as singular; however, one skilled in the art will appreciate that a processing device may include multiple processing elements and multiple types of processing elements. For example, a processing device may include multiple processors or a processor and a controller. In addition, different processing configurations are possible, such as parallel processors, multi-core processors, distributed processing, or the like, that when executing instructions according to firmware or software configure the processing device as a special purpose computer for controlling one or more operations thereof.

The software may include a computer program, a piece of code, an instruction, or some combination thereof, to independently or collectively instruct and/or configure the processing device to operate as desired, thereby transforming the processing device into a special purpose processor. Software and data may be embodied permanently or temporarily in any type of machine, component, physical or virtual equipment, and/or computer storage medium or device. The software also may be distributed over network coupled computer systems so that the software is stored and executed in a distributed fashion. The software and data may be stored by one or more computer readable recording mediums.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

In various example embodiments herein, reference may have been made to various circuit elements, including but not limited to capacitors, resistor, inductors, switches, amplifiers, comparators, filters, and transistors. Various different types of digital, analog, active and/or passive components are available for use in implementing the example embodiments. For example, as discussed above, pseudo-resistors can be substituted for passive resistors. Additionally various different transistor types can be used depending on the implementation, whether positive or negative logic is used, manufacturing processes employed, or the like. Furthermore, unless specifically stated otherwise herein, there are many available types of filters, comparators, switches, and the like that can be used to implement the example embodiments.

While specific language has been used to describe the present subject matter, any limitations arising on account thereto, are not intended. As would be apparent to a person in the art, various working modifications may be made to the method in order to implement the inventive concept as taught herein. The drawings and the foregoing description give examples of example embodiments. Those skilled in the art will appreciate that one or more of the described elements may well be combined into a single functional element. Alternatively, certain elements may be split into multiple functional elements. Elements from one example embodiment may be added to another example embodiment.

We claim:

1. A reference voltage generator comprising:
a start-up circuit configured to receive an input power supply, the start-up circuit comprising a first set of N-channel Metal-Oxide Semiconductor (NMOS) transistors coupled in series, at least one of the first set of NMOS transistors corresponding to a diode connected NMOS transistor configured to form a low impendence node;
a first reference voltage circuit coupled to the start-up circuit and configured to generate a Proportional to Absolute Temperature (PTAT) voltage based on the input power supply, the first reference voltage circuit comprising a second set of NMOS transistors coupled to a current mirror circuit; and
a second reference voltage circuit coupled to the first reference voltage circuit and configured to generate a Complementary to Absolute Temperature (CTAT) voltage based on the input power supply, the second reference voltage circuit comprising a third set of NMOS transistors, at least one of the third set of NMOS transistors corresponding to a diode connected NMOS transistor, the CTAT voltage configured to be combined with the PTAT voltage to generate a reference voltage.

2. The reference voltage generator as claimed in claim 1, further comprising:
a resistive circuit comprising at least one diode-connected MOS resistor, wherein the resistive circuit is configured to generate an independent current output at a common drain-source node of the first reference voltage circuit.

3. The reference voltage generator as claimed in claim 1, wherein the PTAT voltage is generated based on a difference in sizes of NMOS transistors included in the second set of NMOS transistors.

4. The reference voltage generator as claimed in claim 1, wherein the reference voltage is generated based on a multiplication of the PTAT voltage and the CTAT voltage.

5. The reference voltage generator as claimed in claim 1, wherein the first reference voltage circuit is further configured to operate a plurality of NMOS transistors in a subthreshold region.

6. The reference voltage generator as claimed in claim 1, wherein the first reference voltage circuit includes a resistor section and a reference generation branch.

7. The reference voltage generator as claimed in claim 6, wherein the resistor section includes a first NMOS transistor configured to operate as a current source, and a plurality of other NMOS transistors configured to operate as resistors.

8. The reference voltage generator as claimed in claim 1, wherein the PTAT voltage is generated based on a temperature independent bias current.

9. A method comprising:
receiving, an input power supply at a start-up circuit, the start-up circuit including a first set of N-channel Metal-Oxide Semiconductor (NMOS) transistors coupled in series, at least one of the first set of NMOS transistors corresponding to a diode connected NMOS transistor configured to form a low impendence node;
providing the input power supply from the start-up circuit to a first reference voltage circuit and a second reference voltage circuit;
generating, at the first reference voltage circuit, a Proportional to Absolute Temperature (PTAT) voltage based on the input power supply, the first reference voltage circuit comprising a second set of NMOS transistors coupled to a current mirror circuit;
generating, at the second reference voltage circuit, a Complementary to Absolute Temperature (CTAT) voltage based on the input power supply, the second reference voltage circuit comprising a third set of NMOS transistors, at least one of the third set of NMOS transistors corresponding to a diode connected NMOS transistor; and
combining the CTAT voltage with the PTAT voltage to generate a reference voltage.

10. The method as claimed in claim 9, further comprising:
generating, at a resistive circuit comprising at least one diode-connected MOS resistor, an independent current output at a common drain-source node of the first reference voltage circuit.

11. The method as claimed in claim 9, further comprising:
generating the PTAT voltage is based on a difference in sizes of NMOS transistors included in the second set of NMOS transistors.

12. The method as claimed in claim 9, further comprising:
multiplying the PTAT voltage and the CTAT voltage to generate the reference voltage.

13. The method as claimed in claim 9, further comprising:
operating a plurality of NMOS transistors included in the first reference voltage circuit in a subthreshold region.

14. The method as claimed in claim 9, further comprising:
operating a first NMOS transistor included in a resistor section of the first reference voltage circuit as a current source; and
operating a plurality of other NMOS transistors included in the resistor section of the first reference voltage circuit as resistors.

15. The method as claimed in claim 9, further comprising:
generating the PTAT voltage based on a temperature independent bias current.

16. A system comprising:
a voltage divider configured to generate an output including a divided version of a supply voltage;
a reference voltage generator including a startup circuit configured to generate a temperature independent voltage reference (VREF);
a comparator configured to process the temperature independent VREF with the output of the voltage divider to generate a comparator output; and
a failsafe unit and a hysteresis unit configured to receive the comparator output and generate a power-on Reset signal based on the a comparator output.

17. The system as claimed in claim 16, wherein the reference voltage generator includes:
a start-up circuit, the startup circuit being configured to receive an input power supply, the start-up circuit comprising a first set of N-channel Metal-Oxide Semiconductor (NMOS) transistors coupled in series, at least one of the first set of NMOS transistors corresponding to a diode connected NMOS transistor configured to form a low impendence node;
a first reference voltage circuit coupled to the start-up circuit and configured to generate a Proportional to Absolute Temperature (PTAT) voltage based on the input power supply, the first reference voltage circuit comprising a second set of NMOS transistors coupled to a current mirror circuit; and
a second reference voltage circuit coupled to the first reference voltage circuit and configured to generate a Complementary to Absolute Temperature (CTAT) voltage based on the input power supply, the second reference voltage circuit comprising a third set of NMOS transistors, at least one of the third set of NMOS transistors corresponding to a diode connected NMOS transistor, the CTAT voltage configured to be combined with the PTAT voltage to generate a reference voltage.

18. The system as claimed in claim 17, wherein the reference voltage generator further includes:
a resistive circuit comprising at least one diode-connected MOS resistor, wherein the resistive circuit is configured to generate an independent current output at a common drain-source node of the first reference voltage circuit.

19. The system as claimed in claim 17, wherein the PTAT voltage is generated based on a difference in sizes of NMOS transistors included in the second set of NMOS transistors.

20. The system as claimed in claim 17, wherein the reference voltage is generated based on a multiplication of the PTAT voltage and the CTAT voltage.
